(19) United States
(12) Patent Application Publication
(10) Pub. No.: US 2020/0152527 A1
(43) Pub. Date: May 14, 2020

(54) CLEARING OUT METHOD, REVEALING DEVICE, LITHOGRAPHIC APPARATUS, AND DEVICE MANUFACTURING METHOD

(71) Applicant: ASML NETHERLANDS B.V., Veldhoven (NL)

(72) Inventors: Andre Bernardus JEUNINK, Bergeijk (NL); Victoria VORONINA, Veldhoven (NL); Tamara DRUZHININA, Eindhoven (NL); Brennan PETERSON, Longmont, CO (US); Johannes Adrianus Cornelis Maria PIJNENBURG, Moergestel (NL)

(73) Assignee: ASML NETHERLANDS B.V., Veldhoven (NL)

(21) Appl. No.: 16/625,861

(22) PCT Filed: May 28, 2018
(86) PCT No.: PCT/EP2018/063898

§ 371 Date: Dec. 23, 2019

(30) Foreign Application Priority Data
Jul. 5, 2017 (EP) 17179804.4

(51) Int. Cl. H01L 21/66; H01L 23/544; H01L 21/311; G03F 9/00

(52) U.S. Cl. CPC H01L 22/20; H01L 23/544; H01L 2223/54426; G03F 9/7084; H01L 21/31122

(57) ABSTRACT

A method for revealing sensor targets on a substrate covered with a layer, the method including: obtaining locations of first areas on the substrate with yielding target portions and of second areas on the substrate with non-yielding target portions; at least partially removing feature regions of the layer covering sensor targets in the second areas to reveal sensor targets in the second areas; measuring a location of the revealed sensor targets in the second areas; determining a location of sensor targets in the first areas based on the measured location of the revealed sensor targets in the second areas; and at least partially removing sensor target regions of the layer covering the sensor targets in the first areas using the determined location of the sensor targets in the first areas.

### CROSS-REFERENCE TO RELATED APPLICATIONS

This application claims priority of EP application 17179804.4 which was filed on 5 Jul. 2017 and which is incorporated herein in its entirety by reference.

### BACKGROUND

### Field of the Invention

The present invention relates to a method for revealing sensor targets on a substrate, a corresponding revealing device, a lithographic apparatus comprising such a revealing device, and a device manufacturing method.

### Description of the Related Art

A lithographic apparatus is a machine that applies a desired pattern onto a substrate, usually onto a target portion of the substrate. A lithographic apparatus can be used, for example, in the manufacture of integrated circuits (ICs). In such a case, a patterning device, which is alternatively referred to as a mask or a reticle, may be used to generate a circuit pattern to be formed on an individual layer of the IC. This pattern can be transferred onto a target portion (e.g. including part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned. Conventional lithographic apparatus include so-called steppers, in which each target portion is irradiated by exposing an entire pattern onto the target portion at once, and so-called scanners, in which each target portion is irradiated by scanning the pattern through a radiation beam in a given direction (the “scanning”-direction) while synchronously scanning the substrate parallel or anti-parallel to this direction. It is also possible to transfer the pattern from the patterning device to the substrate by imprinting the pattern onto the substrate.

In the lithographic apparatus, sensors are usually provided to measure the position, orientation and/or deformation of a substrate in order to accurately transfer a pattern to a target portion on the substrate. Typically, these sensors use sensor targets provided on the substrate, but when these sensor targets are covered by a layer with unfavorable properties for the sensor, e.g. the layer is opaque for an optically based sensor operating in the visible wavelength range, the measurements are affected in a negative way, for example receiving a too low signal.

Currently, these sensor targets are revealed by clearing out, or removing, a part of the opaque layer which covers the sensor targets using additional lithographic and etching processing steps. These additional processing steps take a lot of time and cost a lot of machine capacity and may result in yield loss.

### SUMMARY

It is desirable to provide an improved process to reveal sensor targets covered by an opaque layer which is quick and preferably does not result in yield loss.

According to an embodiment of the invention, there is provided a method for revealing sensor targets on a substrate covered with a layer, said method comprising the following steps:
a) determining locations of first areas on the substrate with yielding target portions and of second areas on the substrate with non-yielding target portions;
b) at least partially removing feature regions of the layer covering features in the second areas to reveal features in the second areas;
c) measuring a location of the revealed features in the second areas;
d) determining a location of sensor targets in the first areas based on the measured location of the revealed features in the second areas; and
e) removing sensor target regions of the layer covering the sensor targets in the first areas using the determined location of the sensor targets in the first areas.

In an embodiment in step b) at least two features are revealed that are substantially spaced apart.

In an embodiment the steps of removing feature and/or sensor target regions of the layer is carried out by laser ablation.

In an embodiment the method further comprises a step of filling at least the removed sensor target regions.

In an embodiment in step a) non-yielding target portions are at least incomplete target portions at an edge of the substrate.

In an embodiment an area of the feature region is larger than an area of the sensor target region.

In an embodiment measuring a location of the revealed features is carried out using a camera, which is preferably further configured to inspect the clearing out for diagnostic reasons.

According to another embodiment of the invention, there is provided a revealing device configured for revealing sensor targets on a substrate covered with a layer, comprising:
a layer removal device;
a feature location determination device; and
a control unit,
wherein the control unit is configured to receive and/or store information about first areas on the substrate with yielding target portions and second areas on the substrate with non-yielding target portions, wherein the control unit is further configured to:
control the layer removal device to at least partially remove feature regions of the layer covering features in the second areas to reveal the features in the second areas,
control the feature location determination device to measure a location of the revealed features in the second areas;
determine a location of sensor targets in the first areas based on the measured location of the features in the second areas; and
control the layer removal device to remove sensor target regions of the layer covering the sensor targets in the first areas using the determined location of the sensor targets in the first areas.

In an embodiment the layer removal device is a laser.

In an embodiment the feature location determination device is a camera.

In an embodiment an area of the feature region is larger than an area of the sensor target region.

In an embodiment the feature location determination device is further configured to inspect a result of layer removal by the layer removal device.

In an embodiment the revealing device further comprises a filling device to at least fill the removed sensor target regions with another material.

According to yet another embodiment of the invention, there is provided a lithographic apparatus comprising a revealing device according to the invention.

In an embodiment the revealing device is attached to a frame of the lithographic apparatus.

In an embodiment the lithographic apparatus further comprises:
an illumination system configured to condition a radiation beam;
a support constructed to support a patterning device, the patterning device being capable of imparting the radiation beam with a pattern in its cross-section to form a patterned radiation beam;
a substrate table constructed to hold a substrate; and
a projection system configured to project the patterned radiation beam onto a target portion of the substrate.
   According to a further embodiment of the invention, there is provided a device manufacturing method wherein use is made of a revealing device and/or a lithographic apparatus according to the invention.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2 schematically depicts a revealing device according to the invention;

FIG. 3A depicts a top view of a substrate covered with a layer of material;

FIG. 3B depicts a cross-sectional view of the substrate of FIG. 3A;

FIG. 4A depicts a top view of the substrate of FIG. 3A after clearing out features in the second areas;

FIG. 4B depicts in more detail a first region of the substrate of FIG. 4A;

FIG. 4C depicts in more detail a second region of the substrate of FIG. 4A;

FIG. 5A depicts a top view of the substrate of FIG. 4A after clearing out a sensor target in the first areas;

FIG. 5B depicts in more detail a third region of the substrate of FIG. 5A;

FIG. 6 depicts a cross-sectional view of the third region of the substrate of FIG. 5A; and

FIG. 7 depicts a cross-sectional view of the third region of the substrate of FIG. 5A after being filled with another material.

### DETAILED DESCRIPTION

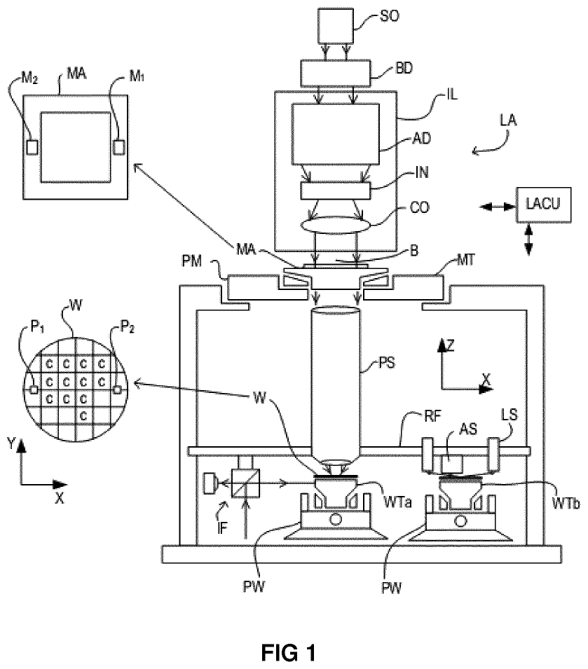

FIG. 1 schematically depicts a lithographic apparatus according to one embodiment of the invention. The apparatus comprises:
an illumination system (illuminator) IL configured to condition a radiation beam B (e.g. UV radiation or EUV radiation).
a support structure (e.g. a mask table) MT constructed to support a patterning device (e.g. a mask) MA and connected to a first positioner PM configured to accurately position the patterning device in accordance with certain parameters;
a substrate table (e.g. a wafer table) WTa or WTb constructed to hold a substrate (e.g. a resist-coated wafer) W and connected to a second positioner PW configured to accurately position the substrate in accordance with certain parameters; and
a projection system (e.g. a refractive projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, and/or controlling radiation.

The support structure MT supports, i.e. bears the weight of, the patterning device MA. It holds the patterning device MA in a manner that depends on the orientation of the patterning device MA, the design of the lithographic apparatus, and other conditions, such as for example whether or not the patterning device MA is held in a vacuum environment. The support structure MT can use mechanical, vacuum, electrostatic or other clamping techniques to hold the patterning device MA. The support structure MT may be a frame or a table, for example, which may be fixed or movable as required. The support structure MT may ensure that the patterning device MA is at a desired position, for example with respect to the projection system PS. Any use of the terms “reticle” or “mask” herein may be considered synonymous with the more general term “patterning device.”

The term “patterning device” used herein should be broadly interpreted as referring to any device that can be used to impart a radiation beam with a pattern in its cross-section such as to create a pattern in a target portion of the substrate W. It should be noted that the pattern imparted to the radiation beam may not exactly correspond to the desired pattern in the target portion of the substrate W, for example if the pattern includes phase-shifting features or so called assist features. Generally, the pattern imparted to the radiation beam will correspond to a particular functional layer in a device being created in the target portion, such as an integrated circuit.

The patterning device MA may be transmissive or reflective. Examples of patterning devices include masks, programmable minor arrays, and programmable LCD panels. Masks are well known in lithography, and include mask types such as binary, alternating phase-shift, and attenuated phase-shift, as well as various hybrid mask types. An example of a programmable minor array employs a matrix arrangement of small mirrors, each of which can be individually tilted so as to reflect an incoming radiation beam in different directions. The tilted mirrors impart a pattern in a radiation beam which is reflected by the minor matrix.

The terms “radiation” and “beam” used herein encompass all types of electromagnetic radiation, including ultraviolet (UV) radiation (e.g. having a wavelength of or about 365, 248, 193, 157 or 126 nm) and extreme ultraviolet (EUV) radiation (e.g. having a wavelength in the range of 5-20 nm), as well as particle beams, such as ion beams or electron beams.

The term “projection system” used herein should be broadly interpreted as encompassing any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. Any use of the term “projection lens” herein may be considered as synonymous with the more general term “projection system”.

As here depicted, the apparatus is of a transmissive type (e.g. employing a transmissive mask). Alternatively, the apparatus may be of a reflective type (e.g. employing a programmable minor array of a type as referred to above, or employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure. The two substrate tables WTa and WTb in the example of FIG. 1 are an illustration of this. The invention disclosed herein can be used in a stand-alone fashion, but in particular it can provide additional functions in the pre-exposure measurement stage of either single- or multi-stage apparatuses.

The lithographic apparatus may also be of a type wherein at least a portion of the substrate W may be covered by a liquid having a relatively high refractive index, e.g. water, so as to fill a space between the projection system PS and the substrate W. An immersion liquid may also be applied to other spaces in the lithographic apparatus, for example, between the patterning device MA and the projection system PS. Immersion techniques are well known in the art for increasing the numerical aperture of projection systems. The term “immersion” as used herein does not mean that a structure, such as a substrate W, must be submerged in liquid, but rather only means that liquid is located between the projection system PS and the substrate W during exposure.

Referring to FIG. 1, the illuminator IL receives a radiation beam from a radiation source SO. The radiation source SO and the lithographic apparatus may be separate entities, for example when the radiation source SO is an excimer laser. In such cases, the radiation source SO is not considered to form part of the lithographic apparatus and the radiation beam is passed from the radiation source SO to the illuminator IL with the aid of a beam delivery system BD comprising, for example, suitable directing mirrors and/or a beam expander. In other cases the source may be an integral part of the lithographic apparatus, for example when the source is a mercury lamp. The radiation source SO and the illuminator IL, together with the beam delivery system BD if required, may be referred to as a radiation system.

The illuminator IL may comprise an adjuster AD for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator IN and a condenser CO. The illuminator may be used to condition the radiation beam, to have a desired uniformity and intensity distribution in its cross-section.

The radiation beam B is incident on the patterning device MA (e.g., mask), which is held on the support structure MT (e.g., mask table), and is patterned by the patterning device MA. Having traversed the patterning device MA, the radiation beam B passes through the projection system PS, which focuses the beam onto a target portion C of the substrate W. With the aid of the second positioner PW and position sensor IF (e.g. an interferometric device, linear encoder or capacitive sensor), the substrate table WTa/WTb can be moved accurately, e.g. so as to position different target portions C in the path of the radiation beam B. Similarly, the first positioner PM and another position sensor (which is not explicitly depicted in FIG. 1) can be used to accurately position the patterning device MA with respect to the path of the radiation beam B, e.g. after mechanical retrieval from a mask library, or during a scan. In general, movement of the support structure MT may be realized with the aid of a long-stroke module (coarse positioning) and a short-stroke module (fine positioning), which form part of the first positioner PM. Similarly, movement of the substrate table WTa/WTb may be realized using a long-stroke module and a short-stroke module, which form part of the second positioner PW. In the case of a stepper (as opposed to a scanner) the support structure MT may be connected to a short-stroke actuator only, or may be fixed. Patterning device MA and substrate W may be aligned using mask alignment marks M1, M2 and substrate alignment marks P1, P2. Although the substrate alignment marks as illustrated occupy dedicated target portions, they may be located in spaces between target portions (these are known as scribe-lane alignment marks). Similarly, in situations in which more than one die is provided on the patterning device MA, the mask alignment marks M1, M2 may be located between the dies.

The depicted apparatus can at least be used in scan mode, in which the support structure MT and the substrate table WTa/WTb are scanned synchronously while a pattern imparted to the radiation beam is projected onto a target portion C (i.e. a single dynamic exposure). The velocity and direction of the substrate table WTa/WTb relative to the support structure MT may be determined by the (de)-magnification and image reversal characteristics of the projection system PS. In scan mode, the maximum size of the exposure field limits the width (in the non-scanning direction) of the target portion in a single dynamic exposure, whereas the length of the scanning motion determines the height (in the scanning direction) of the target portion.

In addition to the scan mode, the depicted apparatus could be used in at least one of the following modes:
1. In step mode, the support structure MT and the substrate table WTa/WTb are kept essentially stationary, while an entire pattern imparted to the radiation beam is projected onto a target portion C at one time (i.e. a single static exposure). The substrate table WTa/WTb is then shifted in the X and/or Y direction so that a different target portion C can be exposed. In step mode, the maximum size of the exposure field limits the size of the target portion C imaged in a single static exposure.
2. In another mode, the support structure MT is kept essentially stationary holding a programmable patterning device, and the substrate table WTa/WTb is moved or scanned while a pattern imparted to the radiation beam is projected onto a target portion C. In this mode, generally a pulsed radiation source is employed and the programmable patterning device is updated as required after each movement of the substrate table WTa/WTb or in between successive radiation pulses during a scan. This mode of operation can be readily applied to maskless lithography that utilizes programmable patterning device, such as a programmable minor array of a type as referred to above.

Combinations and/or variations on the above described modes of use or entirely different modes of use may also be employed.

Lithographic apparatus LA is of a so-called dual stage type which has two substrate tables WTa and WTb and two stations—an exposure station and a measurement station—between which the substrate tables can be exchanged. While one substrate on one substrate table is being exposed at the exposure station, another substrate can be loaded onto the other substrate table at the measurement station so that various preparatory steps may be carried out. The preparatory steps may include mapping the surface of the substrate using a level sensor LS and measuring the position of alignment markers on the substrate using an alignment sensor AS. This enables a substantial increase in the throughput of the apparatus. If the position sensor IF is not capable of measuring the position of the substrate table while it is at the measurement station as well as at the exposure station, a second position sensor may be provided to enable the positions of the substrate table to be tracked at both stations.

The apparatus further includes a lithographic apparatus control unit LACU which controls all the movements and measurements of the various actuators and sensors described. Control unit LACU also includes signal processing and data processing capacity to implement desired calculations relevant to the operation of the apparatus. In practice, control unit LACU will be realized as a system of many sub-units, each handling the real-time data acquisition, processing and control of a subsystem or component within the apparatus. For example, one processing subsystem may be dedicated to servo control of the substrate positioner PW. Separate units may even handle coarse and fine actuators, or different axes. Another unit might be dedicated to the readout of the position sensor IF. Overall control of the apparatus may be controlled by a central processing unit, communicating with these sub-systems processing units, with operators and with other apparatuses involved in the lithographic manufacturing process.

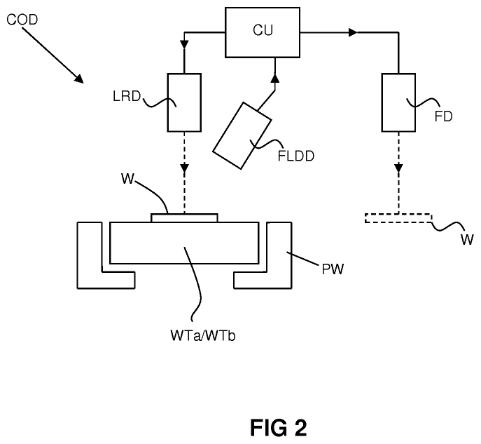

FIG. 2 schematically depicts a revealing device COD according to an embodiment of the invention. The revealing device COD is in this embodiment part of the lithographic apparatus of FIG. 1 and reachable by at least one of the two substrate tables WTa/WTb to provide a substrate W to the revealing device COD.

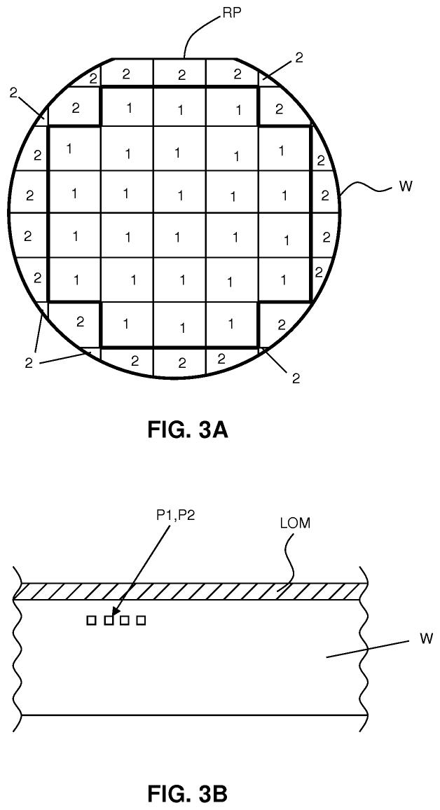

The revealing device COD is configured to reveal, or clear out, sensor targets on a substrate covered with a layer of material. This can be best seen by reference to FIGS. 3A and 3B. FIG. 3A schematically depicts a top view of a substrate W covered with a layer of material and FIG. 3B depicts a cross-sectional view of said substrate W. The substrate W includes sensor targets, for example a substrate alignment mark P1 or P2, e.g. a grating. The substrate W is covered by a layer of material LOM, also covering the sensor targets P1, P2. This layer of material LOM may impede a sensor, such as an alignment sensor, from accurately measuring a position of a sensor target P1, P2, e.g. because the layer of material LOM is opaque for an optically based sensor which is operable in a visible wavelength range, e.g. a carbon layer as occurring in e.g. a 3D NAND process. Clearing out removes a region of the layer of material LOM at least partially such that the sensor targets can be detected with sufficient accuracy by a sensor apparatus. At least partially removing a region of the layer of material LOM thus also includes an embodiment in which a thickness of the layer of material LOM is reduced without completely removing the layer of material. Hence, the thickness of the layer of material LOM may be reduced in a region to a value that the layer of material becomes sufficiently transparent for a wavelength range which is applied by a sensor apparatus to detect a sensor target. At least partially removing the layer of material LOM in a region further also includes completely removing the layer, i.e. reducing the thickness to zero.

In order to clear out the sensor target P1,P2, the revealing device comprises a layer removal device LRD, a feature location determination device FLDD and a filling device FD, all under control or at least in connection with a control unit CU, which may be part of the lithographic apparatus control unit LACU as described in relation to FIG. 1.

Referring to FIG. 3A again, the substrate W comprises first areas indicated by reference symbol ‘1’ comprising yielding target portions and second areas indicated by reference symbol ‘2’ comprising non-yielding target portions. Non-yielding target portions are target portions that are not useful to a manufacturer of e.g. integrated circuits, for example because the target portion is at the edge of the substrate W and not complete, i.e. incomplete, as a result of which it is not possible to yield a working integrated circuit. Yielding target portions are target portions that are useful to a manufacturer of e.g. integrated circuits and able to yield a working integrated circuit.

Information about the expected location of the first areas 1 and the second areas 2 is usually directly or indirectly provided by the manufacturer as it, amongst other things, depends on the target portion size and the distribution of target portions across the substrate, which are all chosen and/or set by the manufacturer. The control unit CU of the revealing device COD in FIG. 2 is configured to receive and/or store this information and to determine an initial, or expected, location of the first and second areas 1,2, and also of the expected locations of the sensor targets and other features on the substrate, based on this information.

The substrate W comprises a reference plane RP or any other reference to allow the revealing device COD to roughly determine the location of the target portions based on the information provided to and/or stored in the control unit CU. However, as the substrate W may be deformed and the sensor targets P1, P2 are covered by the layer of material LOM, it is not possible to determine the position of the sensor targets P1, P2 accurately enough. This may result in a removed region which is not large enough to reveal the entire sensor targets P1, P2, and a part of the sensor target may still be covered by the layer of material LOM. Hence, in order to be sure that an entire sensor target is revealed, and is detectable for a sensor apparatus, it is required to remove a region of the layer covering the sensor target that is substantially larger than the sensor target, which may result in the layer of material also being removed in the first areas above product features as a result of which the product can no longer be finished and yield is reduced.

Hence, in accordance with the invention, first feature regions of the layer in the second areas are at least partially removed to reveal features in the second areas. The area of the feature regions is large enough to reveal the entire features, e.g. entire sensor targets P1, P2, taking into account the relatively low accuracy of the determined location of the sensor targets before the revealing step. The control unit CU is therefore configured to control the layer removal device LRD to at least partially remove feature regions of the layer covering the second areas to reveal features in the second areas. Expected, or initial, locations of the features in the second areas are for example determined, or extracted, from a database comprising a substrate layout in combination with a rough indication of the substrate position, which can for example be determined by detecting an edge of the substrate and/or a reference present at the edge of the substrate, such as a cut-out at the edge of the substrate.

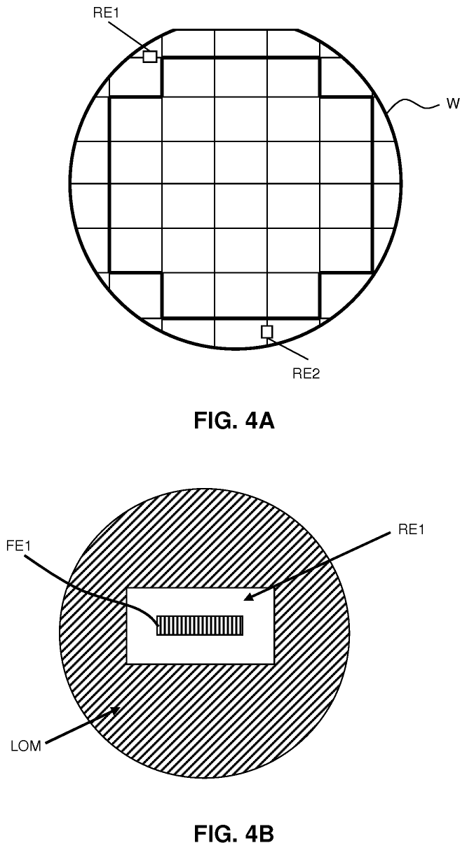

FIG. 4A depicts the substrate W of FIG. 3A, but after the layer removal device LRD has removed the layer of material at a first feature region RE1 and at a second feature region RE2, which first and second feature regions are located in the second areas. In an embodiment the first feature region is located substantially spaced apart from the second feature region, for example the first feature region is in an edge region, or near or at an edge, of the substrate and the second feature region is located in the edge region, or near or at an edge, of the substrate opposite to the first feature region. The layer removal device may for example be a laser, e.g. an ablation laser, configured to remove the layer of material by laser ablation, e.g. the laser is an pulsed laser applying ultra-short pulses, such as a picosecond or femtosecond pulsed laser. In this embodiment, the layer removal device LRD is stationary and the substrate W is moved below the layer removal device LRD using the substrate table WTa/WTb and the corresponding positioner PW. Alternatively or additionally, the layer removal device LRD may be moveable. The layer may also be removed by an etching process, e.g. plasma etching.

FIG. 4B depicts the first feature region RE1 in more detail. By removing the layer of material LOM in the first feature region RE1, a first feature FE1 is revealed. As can be seen, the first feature region RE1 is much larger than the first feature FE1 as the location of the first feature FE1 can't be determined accurately enough. The size of the first feature region RE1 is such that within the error margin of the determination of the location of the first feature FE1, the first feature FE1 will always be revealed. The first feature FE1 may be a sensor target like the sensor targets P1, P2, but may also be another mark, target, grating or any other recognizable feature.

FIG. 4C depicts the second feature region RE2 in more detail. By removing the layer of material LOM in the second feature region RE2, a second feature FE2 is revealed. As can be seen, the second region RE2 is much larger than the second feature FE2 as the location of the second feature FE2 can't be determined accurately enough. The size of the second feature region RE2 is such that within the error margin of the determination of the location of the second feature FE2, the second feature FE2 will always be revealed. The second feature FE2 may be a sensor target like the sensor targets P1, P2, but may also be another mark, target, grating or any other recognizable feature as schematically indicated here.

Once the first and second features FE1, FE2 are revealed, the feature location determination device is controlled to measure a location of the revealed features with greater accuracy than initially was determined, e.g. from a database and/or from substrate edge detection. The results of this measurement can be used to determine a more exact orientation and deformation of the substrate to determine a location of sensor targets P1, P2 in the first areas, e.g. in combination with a database comprising a substrate layout and locations of the sensor targets P1,P2.

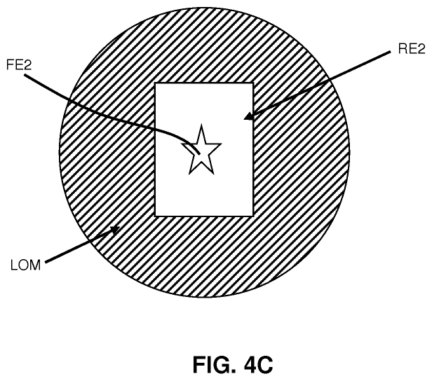

FIG. 5A depicts the substrate W of FIG. 4A, but after determining a location of a sensor target P1, P2 in the first areas at least based on the measured location of the first and second features in the second areas, and controlling the layer removal device to at least partially remove a sensor target region RE3 of the layer and reveal the sensor target in the first areas by at least partially removing the sensor target region of the layer of material covering the sensor target based on the determined location of the sensor target in the second areas.

FIG. 5B depicts the sensor target region RE3 in more detail. By removing the layer of material LOM in the sensor target region RE3, the sensor target P1, P2 is revealed. As can be seen, the size, or area, of the sensor target region RE3 is only slightly larger than the size, or area, of the sensor target P1, P2 because the location of the sensor target is determined more accurately based on the measured locations of the first and second features. As a result, removing the sensor target region of the layer of material will not negatively affect any neighboring target portions, so that yield is not reduced while clearing out the sensor targets.

Although FIGS. 5A and 5B only show the at least partial removal of the sensor target region RE3, i.e. a single sensor target region in the first areas, it will be apparent to the skilled person that using this method, any number of sensor targets, and corresponding sensor target regions, in the first areas can be revealed.

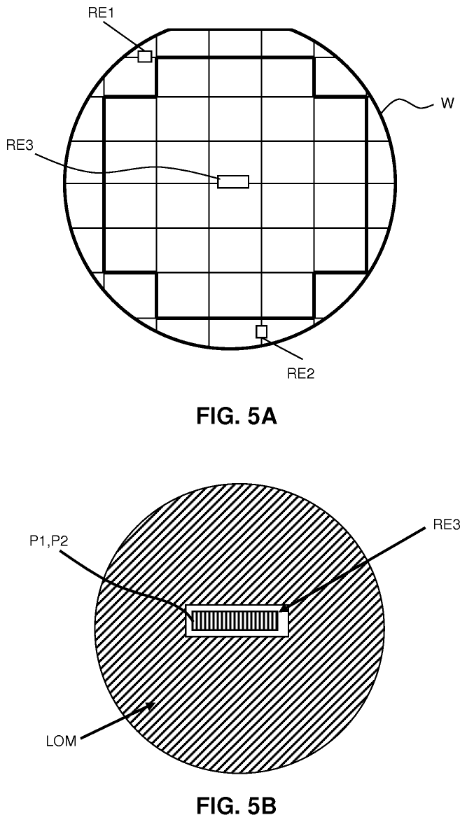

FIG. 6 depicts a cross-sectional view of the sensor target region RE3 of the substrate W of FIG. 5A. It can be clearly seen that the layer of material LOM is removed above the sensor target P1, P2 so that the sensor of the lithographic apparatus is able to interact with the sensor target P1, P2 to determine the position of the sensor target P1, P2 accurately during subsequent processing. However, due to the revealing process, there is a step-like structure surrounding the sensor target so that when a resist layer is spun on the substrate, a non-uniform thickness of the resist layer is obtained.

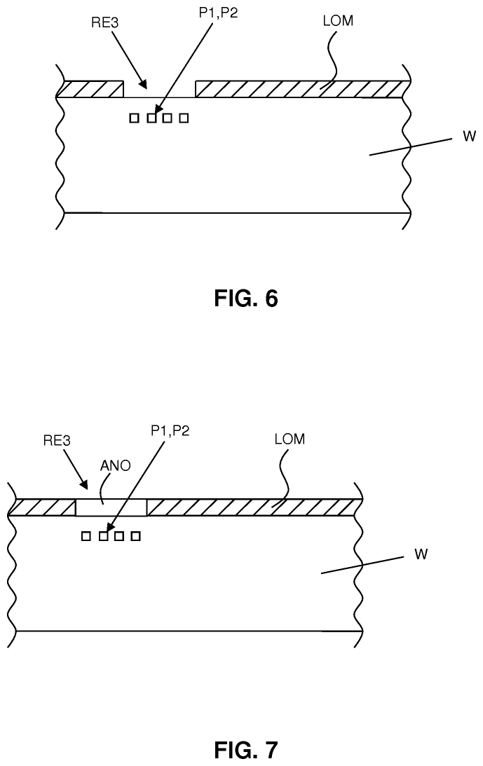

To improve this situation, the sensor target region RE3 may first be filled with another material ANO using the filling device FD as depicted in FIG. 7, which other material is preferably chosen such that it does not impede with the location measurement of the sensor target P1, P2, but provides a flat upper surface of the substrate W to allow a resist layer to be spun on the substrate and obtain a substantially uniform thickness.

The substrate W may for example be brought below the filling device FD as depicted in phantom in FIG. 2 by correspondingly positioning the substrate holder. The material ANO may for example be spin coated on the substrate W in a similar manner as resist is applied to a substrate.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

Although specific reference may have been made above to the use of embodiments of the invention in the context of optical lithography, it will be appreciated that the invention may be used in other applications, for example imprint lithography, and where the context allows, is not limited to optical lithography. In imprint lithography a topography in a patterning device defines the pattern created on a substrate. The topography of the patterning device may be pressed into a layer of resist supplied to the substrate whereupon the resist is cured by applying electromagnetic radiation, heat, pressure or a combination thereof. The patterning device is moved out of the resist leaving a pattern in it after the resist is cured.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1. A method for revealing sensor targets on a substrate covered with a layer, the method comprising:
obtaining locations of first areas on the substrate with yielding target portions and of second areas on the substrate with non-yielding target portions;
at least partially removing feature regions of the layer covering features in the second areas to reveal features in the second areas;
measuring a location of the revealed features in the second areas;
determining a location of sensor targets in the first areas based on the measured location of the revealed features in the second areas; and
at least partially removing sensor target regions of the layer covering the sensor targets in the first areas using the determined location of the sensor targets in the first areas.

2. The method according to claim 1, wherein the at least partially removing the feature regions comprises revealing at least two features that are substantially spaced apart.

3. The method according to claim 1, wherein the at least partially removing the feature and/or sensor target regions of the layer is carried out by laser ablation.

4. The method according to claim 1, further comprising filling at least the removed sensor target regions.

5. The method according to claim 1, wherein non-yielding target portions are at least incomplete target portions at an edge of the substrate.

6. The method according to claim 1, wherein an area of the feature region is larger than an area of the sensor target region.

7. A revealing device configured for revealing sensor targets on a substrate covered with a layer, the revealing device comprising:
a layer removal device;
a feature location determination device; and
a control unit,
wherein the control unit is configured to receive and/or store information about first areas on the substrate with yielding target portions and about second areas on the substrate with non-yielding target portions, and
wherein the control unit is further configured to:
control the layer removal device to at least partially remove feature regions of the layer covering features in the second areas to reveal the-features in the second areas,
control the feature location determination device to measure a location of the revealed features in the second areas,
determine a location of sensor targets in the first areas based on the measured location of the features in the second areas, and
control the layer removal device to remove sensor target regions of the layer covering the sensor targets in the first areas using the determined location of the sensor targets in the first areas.

8. The revealing device according to claim 7, wherein the layer removal device comprises a laser.

9. The revealing device according to claim 7, wherein the feature location determination device comprises is a camera.

10. The revealing device according to claim 7, wherein an area of the feature region is larger than an area of the sensor target region.

11. The revealing device according to claim 7, wherein the feature location determination device is further configured to inspect a result of layer removal by the layer removal device.

12. The revealing device according to claim 7, further comprising a filling device to at least fill the removed sensor target regions with another material.

13. A lithographic apparatus comprising a revealing device according to claim 7.

14. The lithographic apparatus according to claim 13, wherein the revealing device is attached to a frame of the lithographic apparatus.

15. A device manufacturing method wherein use is made of a revealing device according to claim 7.

16. A non-transitory computer program product comprising a computer-readable medium having instructions therein, the instructions, upon execution by a computer system, configured to cause the computer system to at least:
obtain a measured location of revealed features in areas on a substrate with non-yielding target portions, wherein at least partial removal of feature regions of a layer covering features in areas on the substrate with non-yielding target portions caused revealing of the revealed features;
determine a location of sensor targets in areas on the substrate with yielding target portions based on the measured location of the revealed features; and
generate information for causing at least partial removal of sensor target regions of a layer covering the sensor targets in the areas on the substrate with yielding target portions using the determined location of the sensor targets.

17. The computer program product of claim 16, wherein the at least partial removal of the feature and/or sensor target regions of the layer is carried out by laser ablation.

18. The computer program product of claim 16, wherein the instructions are further configured to generate information for filling at least the removed sensor target regions.

19. The computer program product of claim 16, wherein non-yielding target portions are at least incomplete target portions at an edge of the substrate.

20. The computer program product of claim 16, wherein an area of the feature region is larger than an area of the sensor target region.
